(19) United States
(12) Patent Application Publication
(10) Pub. No.: US 2024/0215292 A1
(43) Pub. Date: Jun. 27, 2024

(54) DISPLAY DEVICE AND METHOD OF MANUFACTURING THE SAME

(71) Applicant: SAMSUNG DISPLAY CO., LTD., YONGIN-SI (KR)

(72) Inventors: DAEWON KIM, Yongin-si (KR); JONGHO SON, Yongin-si (KR); HYEBEOM SHIN, Yongin-si (KR); KYUNGHEE LEE, Yongin-si (KR); JINHYEONG LEE, Yongin-si (KR); SUN-YOUNG CHANG, Yongin-si (KR)

(21) Appl. No.: 18/396,236

(22) Filed: Dec. 26, 2023

(30) Foreign Application Priority Data
Dec. 27, 2022 (KR) 10-2022-0186470

(51) Int. Cl. H10K 50/13; H10K 50/844; H10K 50/858

(52) U.S. Cl. CPC H10K 50/131; H10K 50/844; H10K 50/858

(57) ABSTRACT

A display device includes: a base substrate, first, second, and third light emitting diodes disposed on the base substrate and that emits light of different colors, and first, second, and third capping layers respectively disposed on the first, second, and third light emitting diodes, spaced apart from each other, and having different optical thicknesses.

### CROSS-REFERENCE TO RELATED APPLICATION

This application claims priority to and benefits of Korean Patent Application No. 10-2022-0186470 under 35 U.S.C. § 119, filed on Dec. 27, 2022 in the Korean Intellectual Property Office (KIPO), the entire contents of which are hereby incorporated by reference.

### BACKGROUND

### 1. Field

Embodiments provide generally to a display device. More particularly, embodiments provide a display device and a method of manufacturing the same.

### 2. Description Of The Related Art

In recent years, a flat panel display (FPD), which has a large area and can be thin and lightweight, has been widely used as a display device, where the flat panel display may be a liquid crystal display (LCD), a plasma display panel (PDP), an organic light emitting display (OLED), and the like.

An organic light emitting display device may include a plurality of metal patterns or metal film to reflect external light. In order to prevent reflection of the external light, a polarizer may be generally used. However, while the polarizer may prevent reflection of the external light, this can also cause a decrease in transmittance of light emitted from the inside of the organic light emitting display device.

### SUMMARY

Embodiments provide a display device with improved luminous efficiency.

Embodiments provide a method of manufacturing the display device.

A display device according to embodiments of the present disclosure include a base substrate, first, second, and third light emitting diodes disposed on the base substrate, where the first, second, and third light emitting diodes each emit light of a different color, and first, second, and third capping layers respectively disposed on the first, second, and third light emitting diodes, where the first, second, and third capping layers have different optical thicknesses.

In an embodiment, the first, second, and third capping layers may overlap the first, second, and third light emitting diodes, respectively.

In an embodiment, the first light emitting diode may emit red light, the second light emitting diode may emit green light, and the third light emitting diode may emit blue light.

In an embodiment, an optical thickness of each of the first, second, and third capping layers may be defined by multiplying a layer thickness of each of the first, second, and third capping layers by a refractive index of each of the first, second, and third capping layers.

In an embodiment, an optical thickness of the first capping layer may be between about 60 nanometers and about 90 nanometers, an optical thickness of the second capping layer may be between about 20 nanometers and about 50 nanometers, and an optical thickness of the third capping layer may be between about 35 nanometers and about 65 nanometers.

In an embodiment, the first, second, and third capping layers may have a same refractive index.

In an embodiment, the first, second, and third capping layers may include a same material as each other.

In an embodiment, the first, second, and third capping layers may have different layer thicknesses.

In an embodiment, a layer thickness of the first capping layer may be between about 32 nanometers and about 40 nanometers, a layer thickness of the second capping layer may be between about 12 nanometers and about 20 nanometers, and a layer thickness of the third capping layer may be between about 20 nanometers and about 30 nanometers.

In an embodiment, the first, second, and third capping layers may have a same layer thickness as each other.

In an embodiment, the first, second, and third caping layers may include different materials.

In an embodiment, the first, second, and third capping layers may have different refractive indices.

In an embodiment, a refractive index of the first capping layer may be greater than a refractive index of the second capping layer and a refractive index of the third capping layer, and the refractive index of the third capping layer may be greater than the refractive index of the second capping layer.

In an embodiment, each of the first, second, and third capping layers may include an organic material.

In an embodiment, the display device may further include an encapsulation layer disposed on the first, second, and third capping layers and covering the first, second, and third capping layer.

In an embodiment, the display device may further include a reflection control layer disposed on the encapsulation layer.

A display device according to embodiments of the present disclosure include a base substrate, first, second, and third light emitting diodes disposed on the base substrate, where the first, second, and third light emitting diodes each emit light of a different color, and first, second, and third capping layers respectively disposed on the first, second, and third light emitting diodes, where the first, second, and third capping layers have different optical thicknesses, an encapsulation substrate disposed on the first, second, and third capping layers and a filler filling between the first, second, and third capping layers and the encapsulation substrate.

A method of manufacturing a display device according to embodiments of the present disclosure, the method includes forming first, second, and third light emitting diodes that emits light of different colors on a base substrate and forming first, second, and third capping layers having different optical thicknesses on the first, second, and third light emitting diodes.

In an embodiment, the first, second, and third capping layers may have different layer thicknesses.

In an embodiment, the forming the first, second, and third capping layers may include stacking the first, second, and third capping layers having a common layer thickness on the first, second, and third light emitting diodes, and stacking an additional layer thickness other than the common thickness on one or two of the first, second, and third capping layers.

In a display device according to embodiments, the display device may include first, second, and third capping layers having different optical thicknesses. Each of first, second, and third light emitting diodes included in the display device may emit light different from each other. That is, each of the first, second, and third light emitting diodes may emit light having a different wavelength. In this case, since the first, second, and third capping layers are spaced apart from each other and have different optical thicknesses according to the different wavelengths, reflectivity of each of the first, second, and third pixel areas may be minimized.

For this reason, the display device may not include a polarizer. Accordingly, the light emitting efficiency of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a graph illustrating reflectivity of each of the first, second, and third pixel areas of the display device according to the thickness of each of the first, second, and third capping layers.

FIG. 5 is a cross-sectional view illustrating another example of FIG. 3.

FIG. 6 is a cross-sectional view illustrating another example of FIG. 2.

FIG. 7 is a cross-sectional view illustrating another example of FIG. 3.

FIGS. 8, 9, 10, and 11 are views illustrating a method of manufacturing a display device according to an embodiment.

### DETAILED DESCRIPTION OF THE EMBODIMENTS

Hereinafter, a display device according to embodiments of the present disclosure will be explained in detail with reference to the accompanying drawings. The same reference numerals are used for the same components in the drawings, and redundant descriptions of the same components will be omitted.

FIG. 1 is a plan view illustrating a display device according to an embodiment of the present disclosure.

Referring to FIG. 1, a display device 10 according to an embodiment may include a display area DA and a peripheral area PA. The display area DA can include an area that displays an image. The peripheral area PA can include an area that does not display an image. The peripheral area PA may be positioned around the display area DA, where the peripheral area PA may be on four sides of the display area DA. For example, the peripheral area PA may entirely surround the display area DA.

A plurality of pixel areas PX may be disposed in the display area DA, where the pixel areas PX may include a first pixel area PX1, a second pixel area PX2, and a third pixel area PX3. The description of three pixel areas PX is not intended to be limiting, and a greater number of pixel areas PX may be included in the display area DA.

Each of the pixel areas PX, including the first pixel area PX1, the second pixel area PX2, and the third pixel area PX3 include an area where light emitted from a light source, for example, a light emitting diode, is emitted to the outside of the display device 10. For example, the first pixel area PX1 may emit first light, the second pixel area PX2 may emit second light, and the third pixel area PX3 may emit third light. In an embodiment, the first light may be red light, the second light may be green light, and the third light may be blue light. However, the present disclosure is not limited thereto. For example, the pixel areas PX may be combined to emit yellow, cyan, and magenta lights.

In various embodiments, the pixel areas PX may emit light of four or more colors. For example, the pixel areas PX may be combined to further emit at least one of yellow, cyan, and magenta light in addition to red, green, and blue light. In addition, the pixel areas PX may be combined to further emit white light.

In the specification, a plane may be defined as a first direction DR1 and a second direction DR2 intersecting the first direction DR1. For example, the first direction DR1 and the second direction DR2 may be perpendicular to each other.

In a plan view, each of the first pixel area PX1, the second pixel area PX2, and the third pixel area PX3 may be repeatedly arranged along a row direction and a column direction. Specifically, in the plan view, each of the first pixel area PX1, the second pixel area PX2, and the third pixel area PX3 may be repeatedly arranged along the first direction DR1 and the second direction DR2.

Each of the first pixel area PX1, the second pixel area PX2, and the third pixel area PX3 may have a triangular planar shape, a quadrangular planar shape, a circular planar shape, a track-shaped planar shape, an elliptical planar shape, or the like. In an embodiment, each of the first pixel area PX1, the second pixel area PX2, and the third pixel area PX3 may have a rectangular planar shape. However, the present disclosure is not limited thereto, and each of the first pixel area PX1, the second pixel area PX2, and the third pixel area PX3 may have a different planar shape.

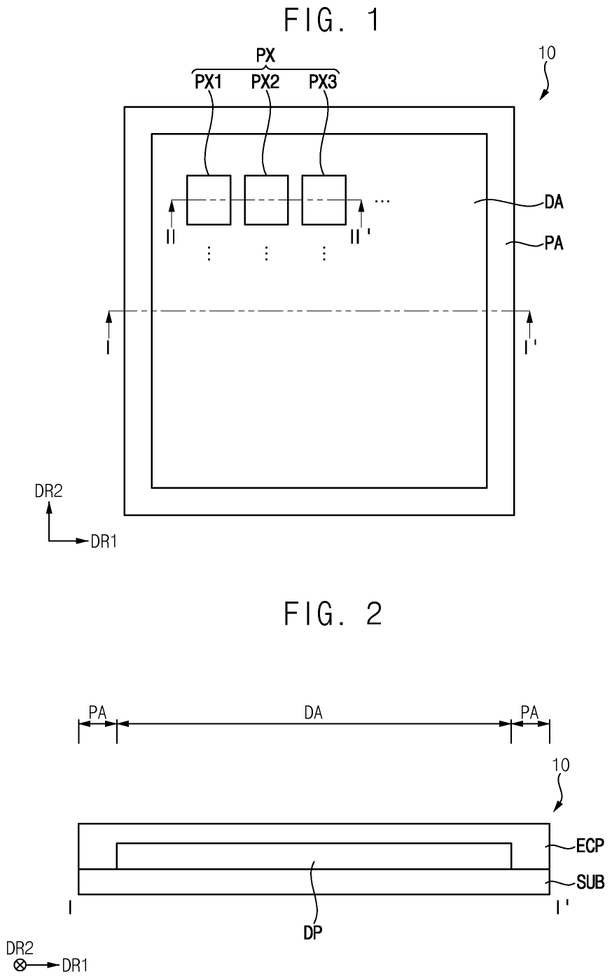

FIG. 2 is a cross-sectional view taken along line I-I′ of FIG. 1.

Referring to FIG. 2, the display device 10 may include a base substrate SUB, a display portion DP, and an encapsulation layer ECP.

The base substrate SUB may be a flexible substrate including a flexible material, such as polyimide, epoxy, polyethylene terephthalate, acryl, silicon, and the like. However, it is not limited thereto, and the base substrate SUB may be a hard substrate including a hard material such as glass, quartz, acryl, polycarbonate, and the like.

The display portion DP may be positioned on the base substrate SUB. The display portion DP may include a plurality of pixels. The plurality of pixels may be arranged in a matrix form in a row direction and a column direction. The plurality of pixels may overlap each of the plurality of pixel areas PX.

Each pixel may include a light emitting diode and a pixel circuit connected to the light emitting diode. The pixel circuit may include at least one thin film transistor and at least one capacitor. However, embodiments according to the present disclosure are not limited thereto, and in other embodiments, other than the light emitting diode, other elements applicable to the display device 10 may constitute the display portion DP.

The encapsulation layer ECP may be disposed on the display portion DP. The encapsulation layer ECP may cover the display portion DP, including a top surface and the sidewalls of the display portion DP. The encapsulation layer ECP may prevent penetration of moisture and/or air into the display portion DP, where the encapsulation layer ECP covers the entire display portion DP. The encapsulation layer ECP can cover the peripheral area PA, where the encapsulation layer ECP extends laterally beyond the edges of the display portion DP and covers the sidewalls. The encapsulation layer ECP may be coextensive with the base substrate SUB. The encapsulation layer ECP may include a plurality of encapsulation layers. The encapsulation layer ECP may include an inorganic encapsulation layer and an organic encapsulation layer that are alternately stacked. For example, the inorganic encapsulation layer may include silicon oxide, silicon nitride, and silicon oxynitride, and the like. These may be used alone or in combination with each other. The organic encapsulation layer may include a polymer cured material such as polyacrylate and the like. However, the present disclosure is not limited thereto.

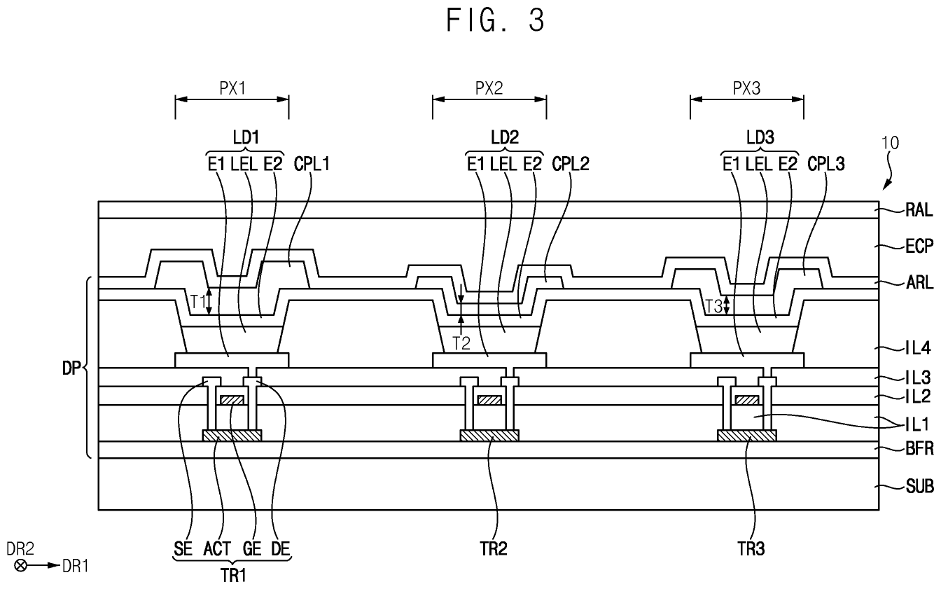

FIG. 3 is a cross-sectional view taken along line II-II′ of FIG. 1.

Referring to FIGS. 2 and 3, the display device 10 may include the base substrate SUB, the display portion DP, the encapsulation layer ECP, and a reflection adjusting layer RAL, where the encapsulation layer ECP can be on the display portion DP and base substrate SUB, and the reflection adjusting layer RAL can be on the encapsulation layer ECP. The display portion DP may include a buffer layer BFR, a plurality of thin film transistors, a plurality of insulating layers, a plurality of light emitting diodes, a plurality of capping layers, and an anti-reflection layer ARL.

The base substrate SUB may include a transparent or opaque material. For example, the base substrate SUB may be a rigid substrate made of quartz or glass. For another example, the base substrate SUB may be a flexible substrate made of polyimide or the like. The flexible substrate may have a structure in which polyimide layers and barrier layers are alternately stacked.

The buffer layer BFR may be disposed on the base substrate SUB, where the buffer layer BFR can physically separate the base substrate SUB from the overlying layers of the display portion DP. The buffer layer BFR may prevent diffusion of impurities such as oxygen and moisture to an upper portion of the base substrate SUB through the base substrate SUB. The buffer layer BFR may include an inorganic material, for example, a silicon compound, a metal oxide, and the like. The buffer layer BFR may have a single-layer structure or a multi-layer structure including a plurality of insulating layers.

The plurality of thin film transistors may include first, second, and third thin film transistors TR1, TR2, and TR3. The first, second, and third thin film transistors TR1, TR2, and TR3 may be disposed on the buffer layer BFR, where the buffer layer can separate the first, second, and third thin film transistors TR1, TR2, and TR3 from the substrate.

Each of the first, second, and third thin film transistors TR1, TR2, and TR3 may include an active layer ACT, a gate electrode GE, a source electrode SE, and a drain electrode DE.

The active layer ACT may be disposed on the buffer layer BFR. The active layer ACT may include an oxide semiconductor, a silicon semiconductor, an organic semiconductor, or the like. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), zinc (Zn), and the like. The silicon semiconductor may include amorphous silicon, polycrystalline silicon, and the like.

The first insulating layer IL1 may be disposed on the buffer layer BFR, where the first insulating layer IL1 may be in direct contact with portions of the buffer layer BFR. The first insulating layer IL1 may cover at least portions of the active layer ACT, where the first insulating layer IL1 may be between the source electrode SE and the drain electrode DE and on the edges of the active layer ACT. For example, the first insulating layer IL1 may include an inorganic material. Accordingly, the first insulating layer IL1 may be disposed with substantially the same thickness along the profile of the active layer ACT. However, the present disclosure is not limited thereto.

The gate electrode GE may be disposed on the first insulating layer IL1. The gate electrode GE may overlap the active layer ACT. For example, the gate electrode GE may include metal.

The second insulating layer IL2 may be disposed on the first insulating layer IL1. The second insulating layer IL2 may cover the gate electrode GE. For example, the second insulating layer IL2 may include an inorganic material. The second insulating layer IL2 may be disposed with substantially the same thickness along the profile of the gate electrode GE. However, the present disclosure is not limited thereto.

The source electrode SE and the drain electrode DE may be disposed on the second insulating layer IL2, where the source electrode SE and the drain electrode DE may extend through the second insulating layer IL2 and the first insulating layer IL1 to the active layer ACT. The source electrode SE and the drain electrode DE may be electrically connected to the active layer ACT. For example, the source electrode SE and the drain electrode DE may include metal.

A third insulating layer IL3 may be disposed on the second insulating layer IL2. The third insulating layer IL3 may cover the source electrode SE and the drain electrode DE. For example, the third insulating layer IL3 may include an organic material. The third insulating layer IL3 may have a substantially flat upper surface without creating a step around the source and drain electrodes SE and DE. However, the present disclosure is not limited thereto.

The plurality of light emitting diodes may include first, second, and third light emitting diodes LD1, LD2, and LD3, where the first, second, and third light emitting diodes LD1, LD2, and LD3 can be laterally adjacent to each other. The first, second, and third light emitting diodes LD1, LD2, and LD3 may be disposed on the third insulating layer IL3. The first light emitting diode LED1 may overlap the first pixel area PX1, the second light emitting diode LED2 may overlap the second pixel area PX2, and the third light emitting diode LED3 may overlap the third pixel area PX3. The first light emitting diode LED1 may overlap the first thin film transistors TR1, the second light emitting diode LED2 may overlap the second thin film transistors TR2, and the third light emitting diode LED3 may overlap the third thin film transistors TR3.

In an embodiment, the first, second, and third light emitting diodes LD1, LD2, and LD3 may emit light of different colors. The first, second, and third light emitting diodes LD1, LD2, and LD3 may generate light of different colors. For example, the first light emitting diode LD1 may emit the first light, where the first light may be red light. The second light emitting diode LD2 may emit the second light, where the second light may be green light. The third light emitting diode LD3 may emit the third light, where the third light may be blue light. However, the present disclosure is not limited thereto.

Each of the first, second, and third light emitting diodes LD1, LD2, and LD3 may include a first electrode E1, a light emitting layer LEL, and a second electrode E2, where the light emitting layer LEL can be between the first electrode E1 and the second electrode E2. Each of the first, second, and third light emitting diodes LD1, LD2, and LD3 may include a portion where the first electrode E1, the light emitting layer LEL, and the second electrode E2 overlap each other.

The first electrode E1 may be disposed on the third insulating layer IL3. The first electrode E1 may have reflective or light-transmitting properties. For example, the first electrode E1 may include metal.

The first electrode E1 may contact the source electrode SE or the drain electrode DE through a third contact hole formed in the third insulating layer IL3, where a portion of the first electrode E1 may extend partially through the third insulating layer IL3. The first electrode E1 may be electrically connected to a thin film transistor through the source electrode SE or the drain electrode DE.

A fourth insulating layer IL4 may be disposed on at least a portion of the first electrode E1. The fourth insulating layer IL4 may include an organic material. The fourth insulating layer IL4 may include a pixel opening exposing at least a portion of the first electrode E1.

The light emitting layer LEL may be disposed on the first electrode E1 exposed by the pixel opening of the fourth insulating layer IL4. Adjacent pairs of the first, second, and third light emitting diodes LD1, LD2, and LD3 may be separated by an intervening portion of the fourth insulating layer IL4.

The light emitting layer LEL may include at least one of an organic light emitting material and a quantum dot. In an embodiment, the light emitting layer LEL included in the first light emitting diode LD1 may generate red light. The light emitting layer LEL included in the second light emitting diode LD2 may generate green light. The light emitting layer LEL included in the third light emitting diode LD3 may generate blue light. However, embodiments of the present disclosure are not limited thereto.

In various embodiments, the light emitting layer LEL may be formed in multiple layers and may have a structure in which a plurality of organic light emitting layers are stacked. For example, the light emitting layer LEL may have a structure in which three organic light emitting layers are stacked. However, the present disclosure is not limited thereto.

In an embodiment, the plurality of capping layers may include first, second, and third capping layers CPL1, CPL2, and CPL3. The first, second, and third capping layers CPL1, CPL2, and CPL3 may be respectively disposed on the first, second, and third light emitting diodes LD1, LD2, and LD3. For example, the first capping layer CPL1 may be disposed on the first light emitting diode LD1, and the second capping layer CPL2 may be disposed on the second light emitting diode LD2, and the third capping layer CPL3 may be disposed on the third light emitting diode LD3. In addition, the first, second, and third capping layers CPL1, CPL2, and CPL3 may overlap the first, second, and third light emitting diodes LD1, LD2, and LD3, respectively. Each of the first, second, and third capping layers CPL1, CPL2, and CPL3 may cover a different portion of the second electrode E2. Each of the first, second, and third capping layers CPL1, CPL2, and CPL3 may include an organic material. For example, each of the first, second, and third capping layers CPL1, CPL2, and CPL3 may include-NPD, NPB, TPD, m-MTDATA, Alq₃, CuPc, TPD15(N4,N4,N4′,N4′-tetra (biphenyl-4-yl) biphenyl-4,4′-diamine), TCTA(4,4′,4″-Tris (carbazol-9-yl) triphenylamine), an epoxy resin, an acrylate-based resin, and the like. These may be used alone or in combination with each other. However, the present disclosure is not limited thereto.

In an embodiment, the first, second, and third capping layers CPL1, CPL2, and CPL3 may be spaced apart from each other. The first capping layer CPL1 may overlap the first pixel area PX1, the second capping layer CPL2 may overlap the second pixel area PX2, and the third capping layer CPL3 may overlap the third pixel area PX3.

The first, second, and third capping layers CPL1, CPL2, and CPL3 may have different optical thicknesses. In this case, the optical thickness may be defined by multiplying a capping layer thickness by a refractive index, where the refractive index may be related to the color of the light being emitted. The optical thickness of each of the first, second, and third capping layers CPL1, CPL2, and CPL3 may be defined by multiplying a thickness of each of the first, second, and third capping layers CPL1, CPL2, and CPL3 by a refractive index of each of the first, second, and third capping layers CPL1, CPL2, and CPL3.

In an embodiment, the optical thickness of the first capping layer CPL1 may be between about 60 nanometers and about 90 nanometers. The optical thickness of the second capping layer CPL2 may be between about 20 nanometers and about 50 nanometers. The optical thickness of the third capping layer CPL3 may be between about 35 nanometers and about 65 nanometers.

In an embodiment, the first, second, and third capping layers CPL1, CPL2, and CPL3 may have the same refractive index. That is, the first, second, and third capping layers CPL1, CPL2, and CPL3 may include the same material as each other.

In this case, the first, second, and third capping layers CPL1, CPL2, and CPL3 may have different thicknesses. A thickness T1 of the first capping layer CPL1 may be greater than a thickness T2 of the second capping layer CPL2 and a thickness T3 of the third capping layer CPL3 may be greater than the thickness T2 of the second capping layer CPL2. For example, the layer thickness T1 of the first capping layer CPL1 may be between about 32 nanometers and about 40 nanometers. The layer thickness T2 of the second capping layer CPL2 may be between about 12 nanometers and about 20 nanometers. The layer thickness T3 of the third capping layer CPL3 may be between about 20 nanometers and about 30 nanometers.

The anti-reflection layer ARL may be disposed on the first, second, and third capping layers CPL1, CPL2, and CPL3, as well as exposed portions of the second electrode E2. The anti-reflection layer ARL may entirely cover the second electrode E2 and the first, second, and third capping layers CPL1, CPL2, and CPL3. However, the present disclosure is not limited thereto.

The encapsulation layer ECP may be disposed on the anti-reflection layer ARL, where the encapsulation layer ECP can cover steps formed by the anti-reflection layer ARL and first, second, and third capping layers CPL1, CPL2, and CPL3. The encapsulation layer ECP may cover the anti-reflection layer ARL.

The reflection control layer RAL may be disposed on the encapsulation layer ECP. The reflection control layer RAL may be entirely disposed on the encapsulation layer ECP. In this case, a polarizer may not be disposed on the encapsulation layer ECP. The reflection control layer RAL may include an organic material and the like. The reflection control layer RAL may include a light absorbing material. For example, the reflection control layer RAL may include a tetra aza porphyrin (TAP)-based compound, a porphyrin-based compound, a metal porphyrin-based compound, an oxazine-based compound, a squarylium-based compound, a triarylmethane-based compound, a polymethine-based compound, a traquinone-based compound, a phthalocyanine-based compound, an azo-based compound, a perylene-based compound, an xanthene-based compound, a diimmonium-based compound, a dipyrromethene-based compound, a cyanine-based compound, and the like. However, the present disclosure is not limited thereto.

In an embodiment, the encapsulation layer ECP may cover the display portion DP and fill an empty space between the anti-reflection layer ARL and the reflection adjusting layer RAL. The encapsulation layer ECP can provide a flat surface for disposition of the reflection adjusting layer RAL.

A touch sensing layer may be further disposed on the reflection adjusting layer RAL. The touch sensing layer may function as an input means of the display device 10. However, the present disclosure is not limited thereto, and the touch sensing layer may be disposed between the encapsulation layer ECP and the reflection adjusting layer RAL.

In an embodiment, the display device 10 may include the first, second, and third capping layers CPL1, CPL2, and CPL3 having different optical thicknesses. Each of the first, second, and third light emitting diodes LD1, LD2, and LD3 may emit light different from each other, where each of the first, second, and third light emitting diodes LD1, LD2, and LD3 may emit light having a different wavelength. In this case, since the first, second, and third capping layers CPL1, CPL2, and CPL3 are spaced apart from each other and have different optical thicknesses according to the different wavelengths, reflectivity of each of the first, second, and third pixel areas PX1, PX2, and PX3 may be minimized. For this reason, the display device 10 may not include the polarizer. Accordingly, the light emitting efficiency of the display device 10 may be improved.

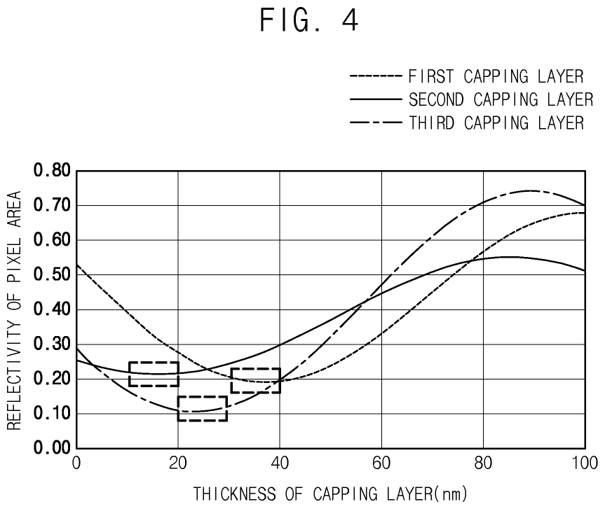

FIG. 4 is a graph illustrating reflectivity of each of the first, second, and third pixel areas of the display device according to the thickness of each of the first, second, and third capping layers.

Referring FIGS. 3 and 4, the x-axis of the graph of FIG. 4 indicates the thickness of each of the first, second, and third capping layers CPL1, CPL2, and CPL3, and the y-axis of the graph of FIG. 4 indicates the reflectivity of each of the first, second, and third pixel areas PX1, PX2, and PX3.

Referring to the graph of the first, second, and third capping layers CPL1, CPL2, and CPL3, it can be seen that a section in which the reflectivity of the first pixel area PX1 of the display device 10 is at a minimum is a section in which the layer thickness T1 of the first capping layer CPL1 is about 32 nanometers to about 40 nanometers. In addition, it can be seen that a section in which the reflectivity of the second pixel area PX2 of the display device 10 is at a minimum is a section in which the layer thickness T2 of the second capping layer CPL2 is about 12 nanometers to about 20 nanometers. Furthermore, it can be seen that a section in which the reflectivity of the third pixel area PX3 of the display device 10 is at a minimum is a section in which the layer thickness T3 of the third capping layer CPL3 is about 12 nanometers to about 20 nanometers.

In an embodiment, each of the first, second, and third capping layers CPL1, CPL2, and CPL3 has a thickness that minimizes reflectivity of each of the first, second, and third pixel areas PX1, PX2, and PX3, respectively, where a reflectivity of each of the first, second, and third pixel areas PX1, PX2, and PX3 may be minimized. For at least this reason, the display device 10 may not include the polarizer. Accordingly, the light emitting efficiency of the display device 10 may be improved.

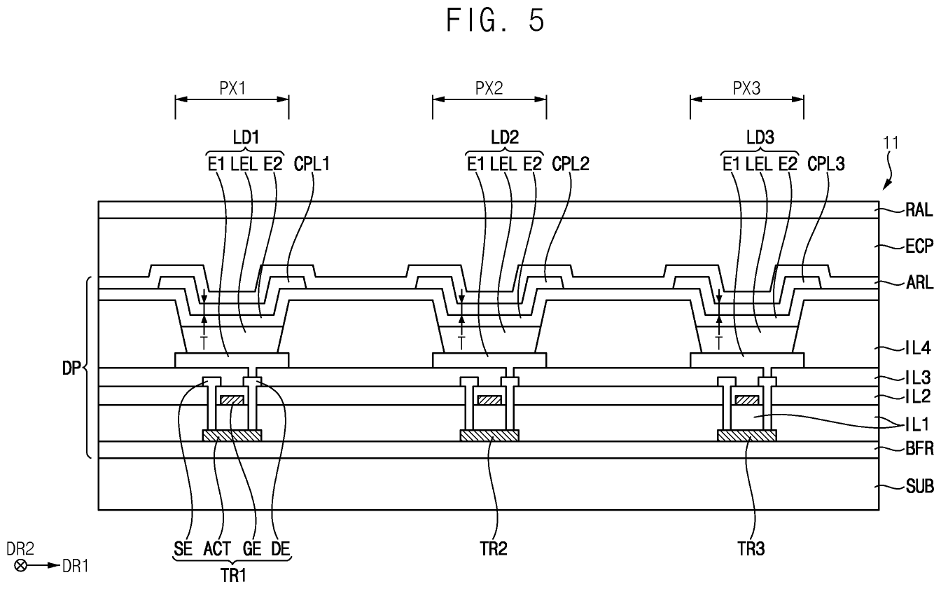

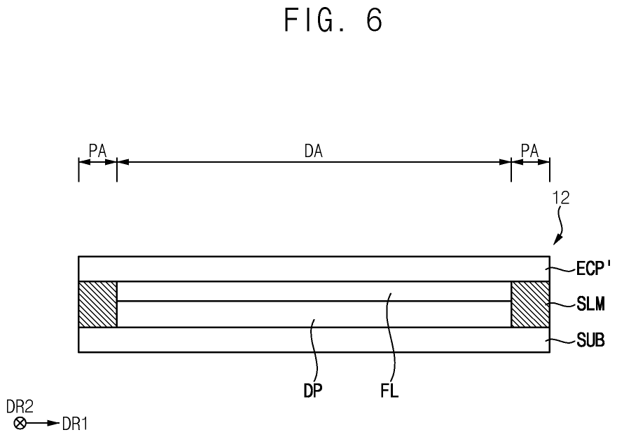

FIG. 5 is a cross-sectional view illustrating another example of FIG. 3.

For example, a display device 11 described with reference to FIG. 5 may be the same as the display device 10 described with reference to FIG. 3 except for the first, second, and third capping layers CPL1, CPL2, and CPL3. Accordingly, redundant descriptions may be omitted or simplified.

Referring to FIG. 5, the display device 11 may include a base substrate SUB, a display portion DP, an encapsulation layer ECP, and a reflection adjusting layer RAL. The display portion DP may include a buffer layer BFR, a plurality of thin film transistors, a plurality of insulating layers, a plurality of light emitting diodes, a plurality of capping layers, and an anti-reflection layer ARL. The encapsulation layer ECP can cover the display portion DP.

In an embodiment, the plurality of capping layers may include first, second, and third capping layers CPL1, CPL2, and CPL3. The first, second, and third capping layers CPL1, CPL2, and CPL3 may be respectively disposed on the first, second, and third light emitting diodes LD1, LD2, and LD3. In addition, the first, second, and third capping layers CPL1, CPL2, and CPL3 may overlap the first, second, and third light emitting diodes LD1, LD2, and LD3, respectively. Each of the first, second, and third capping layers CPL1, CPL2, and CPL3 may include an organic material.

In an embodiment, the first, second, and third capping layers CPL1, CPL2, and CPL3 may be spaced apart from each other. The first capping layer CPL1 may overlap the first pixel area PX1, the second capping layer CPL2 may overlap the second pixel area PX2, and the third capping layer CPL3 may overlap the third pixel area PX3.

The first, second, and third capping layers CPL1, CPL2, and CPL3 may have different optical thicknesses. In this case, the optical thickness may be defined by multiplying a thickness by a refractive index. That is, the optical thickness of each of the first, second, and third capping layers CPL1, CPL2, and CPL3 may be defined by multiplying a thickness of each of the first, second, and third capping layers CPL1, CPL2, and CPL3 by a refractive index of each of the first, second, and third capping layers CPL1, CPL2, and CPL3.

In an embodiment, the optical thickness of the first capping layer CPL1 may be between about 60 nanometers and about 90 nanometers. The optical thickness of the second capping layer CPL2 may be between about 20 nanometers and about 50 nanometers. The optical thickness of the third capping layer CPL3 may be between about 35 nanometers and about 65 nanometers.

In an embodiment, the first, second, and third capping layers CPL1, CPL2, and CPL3 may have the same layer thickness T as each other. In this case, the first, second, and third capping layers CPL1, CPL2, and CPL3 may have different refractive indices, n. That is, the first, second, and third capping layers CPL1, CPL2, and CPL3 may include different materials. For example, the refractive index of each of the first, second, and third capping layers CPL1, CPL2, and CPL3 may be about 1.5 to about 2.5. However, the present disclosure is not limited thereto.

In an embodiment, the refractive index, n, of the first capping layer CPL1 may be greater than the refractive index of the second capping layer CPL2 and the refractive index of the third capping layer CPL3. The refractive index of the third capping layer CPL3 may be greater than the refractive index of the second capping layer CPL2, such that n_{CPL2}<n_{CPL3}<n_{CPL1}.

In an embodiment, the display device 11 may include the first, second, and third capping layers CPL1, CPL2, and CPL3 having different optical thicknesses. Each of the first, second, and third light emitting diodes LD1, LD2, and LD3 may emit light having a different wavelength. In this case, because the first, second, and third capping layers CPL1, CPL2, and CPL3 are spaced apart from each other and have different optical thicknesses according to the different wavelengths, reflectivity of each of the first, second, and third pixel areas PX1, PX2, and PX3 may be minimized. Each of the first, second, and third capping layers CPL1, CPL2, and CPL3 has a thickness that minimizes reflectivity of each of the first, second, and third pixel areas PX1, PX2, and PX3, respectively, where a reflectivity of each of the first, second, and third pixel areas PX1, PX2, and PX3 may be minimized. For this reason, the display device 11 may not include the polarizer. Accordingly, the light emitting efficiency of the display device 11 may be improved.

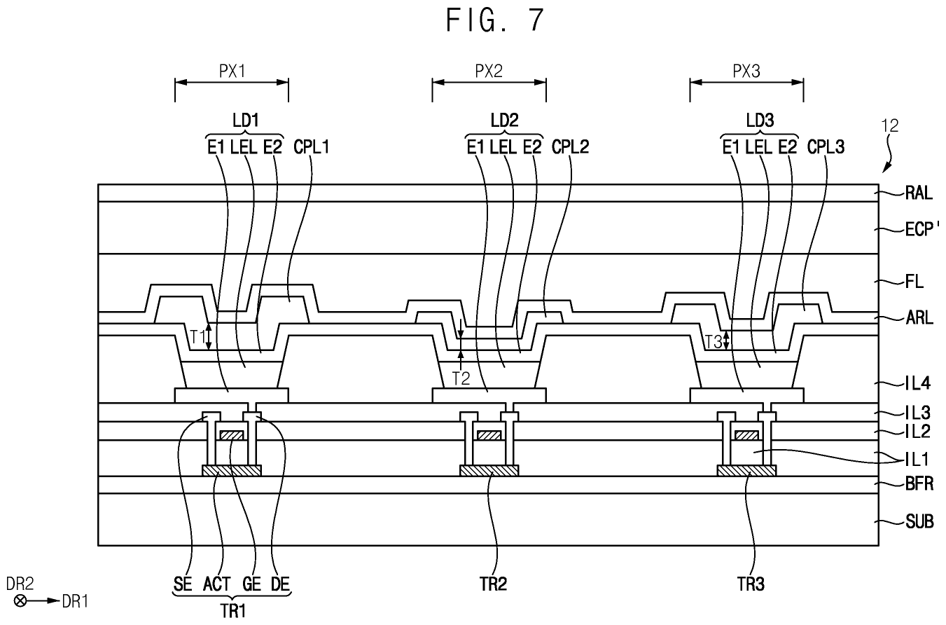

FIG. 6 is a cross-sectional view illustrating another example of FIG. 2. FIG. 7 is a cross-sectional view illustrating another example of FIG. 3.

For example, a display device 12 described with reference to FIGS. 6 and 7 may be the same as the display device 10 described with reference to FIGS. 2 and 3 except for a filler FL and an encapsulation substrate ECP′. Accordingly, redundant descriptions may be omitted or simplified.

Referring to FIGS. 6 and 7, the display device 12 may include a base substrate SUB, a display portion DP, the encapsulation substrate ECP′, and a sealing member SLM. The display portion DP may include a buffer layer BFR, a plurality of thin film transistors, a plurality of insulating layers, a plurality of light emitting diodes, a plurality of capping layers, and an anti-reflection layer ARL. The filler FL may be between opposing sealing members SLMs, and cover the display portion DP, where the filler FL can be between the display portion DP and the encapsulation substrate ECP′. The display portion DP can separate the filler FL from the base substrate SUB.

The base substrate SUB may be a hard substrate including a hard material such as glass, quartz, acryl, polycarbonate, and the like. However, it is not limited thereto, and the base substrate SUB may be a flexible substrate including a flexible material such as polyimide, epoxy, polyethylene terephthalate, acryl, silicon, and the like.

The display unit DP may be positioned on the base substrate SUB. The display portion DP may include a plurality of pixels. The plurality of pixels may be arranged in a matrix form in a row direction and a column direction. The plurality of pixels may overlap each of the plurality of pixel areas.

The encapsulation substrate ECP′ may be disposed to face the base substrate SUB. The encapsulation substrate ECP′ may be bonded to the base substrate SUB through the sealing member SLM and/or the filler FL. The encapsulation substrate ECP′ may be disposed on the display portion DP. The encapsulation substrate ECP′ may prevent penetration of moisture and/or air into the display portion DP.

The sealing member SLM may be disposed between the encapsulation substrate ECP′ and the base substrate SUB. The sealing member SLM may bond the encapsulation substrate ECP′ and the base substrate SUB. The sealing member SLM may overlap the peripheral area PA and cover a side surface of the display portion DP.

The filler FL may fill a space between the encapsulation substrate ECP′ and the display portion DP, where the filler FL may be in physical contact with a lower surface of the encapsulation substrate ECP′ and an upper surface of the display portion DP. Specifically, the filler FL may be disposed on the anti-reflection layer ARL and may be disposed under the encapsulation substrate ECP′, where the filler FL can cover steps formed by the anti-reflection layer ARL and first, second, and third capping layers CPL1, CPL2, and CPL3, and provide a flat surface for the encapsulation substrate ECP′.

The plurality of capping layers may include first, second, and third capping layers CPL1, CPL2, and CPL3. The first, second, and third capping layers CPL1, CPL2, and CPL3 may be respectively disposed on the first, second, and third light emitting diodes LD1, LD2, and LD3. In addition, the first, second, and third capping layers CPL1, CPL2, and CPL3 may overlap the first, second, and third light emitting diodes LD1, LD2, and LD3, respectively.

In an embodiment, the first, second, and third capping layers CPL1, CPL2, and CPL3 may be spaced apart from each other and may have different optical thicknesses. For example, the first, second, and third capping layers CPL1, CPL2, and CPL3 may have different thicknesses T1, T2, and T3. However, the present disclosure is not limited thereto, and for another example, the first, second, and third capping layers CPL1, CPL2, and CPL3 may have different refractive indices.

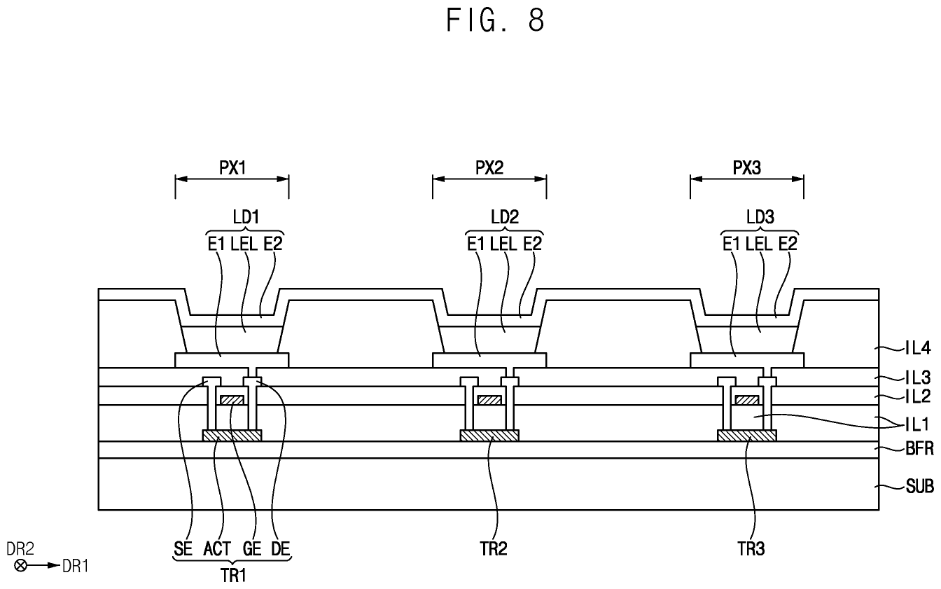

FIGS. 8, 9, 10, and 11 are views illustrating a method of manufacturing a display device according to an embodiment.

For example, the method of manufacturing the display device described with reference to FIGS. 8, 9, 10, and 11 may be the method of manufacturing the display device 10 of FIG. 3. Accordingly, redundant descriptions may be omitted or simplified.

Referring to FIG. 8, the base substrate SUB may be prepared. The buffer layer BFR, a plurality of thin film transistors, a plurality of insulating layers, and a plurality of light emitting diodes may be sequentially formed on the base substrate SUB.

The plurality of light emitting diodes may include the first, second, and third light emitting diodes LD1, LD2, and LD3. The first, second, and third light emitting diodes LD1, LD2, and LD3 may be formed on the third insulating layer IL3.

Specifically, the first electrodes E1 may be formed on the third insulating layer IL3. The first electrodes E1 formed for each of the first, second, and third light emitting diodes LD1, LD2, and LD3 may be spaced apart from each other. The fourth insulating layer IL4 may be formed on the first electrodes E1, where the fourth insulating layer IL4 can separate adjacent pairs of the first electrodes E1 and light emitting diodes. Openings may be formed in the fourth insulating layer IL4 to partially expose the first electrodes E1.

The light emitting layers LEL may be formed in the openings on the first electrodes E1, where a top surface of the light emitting layers can be lower than a top surface of the fourth insulating layer IL4. The light emitting layers LEL may be spaced apart from each other, where the fourth insulating layer IL4 can separate adjacent pairs of the light emitting layers LEL. However, the present disclosure is not limited thereto. The second electrode E2 may be formed on the light emitting layers LEL and the fourth insulating layer IL4, where the difference in height between the top surface of the fourth insulating layer IL4 and the top surface of the light emitting layers LEL can form steps. The second electrode E2 can be formed over the steps.

The first electrode E1, the light emitting layer LEL, and the second electrode E2 overlapping the first pixel area PX1 may form the first light emitting diode LD1. The first electrode E1, the light emitting layer LEL, and the second electrode E2 overlapping the second pixel area PX2 may form the second light emitting diode LD2. The first electrode E1, the light emitting layer LEL, and the second electrode E2 overlapping the third pixel area PX3 may form the third light emitting diode LD3. The first, second, and third light emitting diodes LD1, LD2, and LD3 may emit light of different colors.

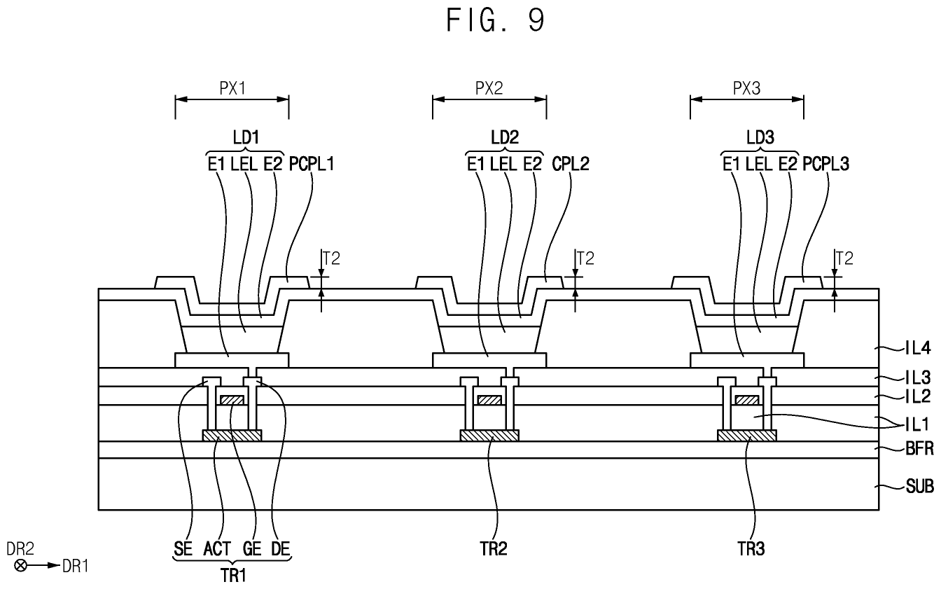

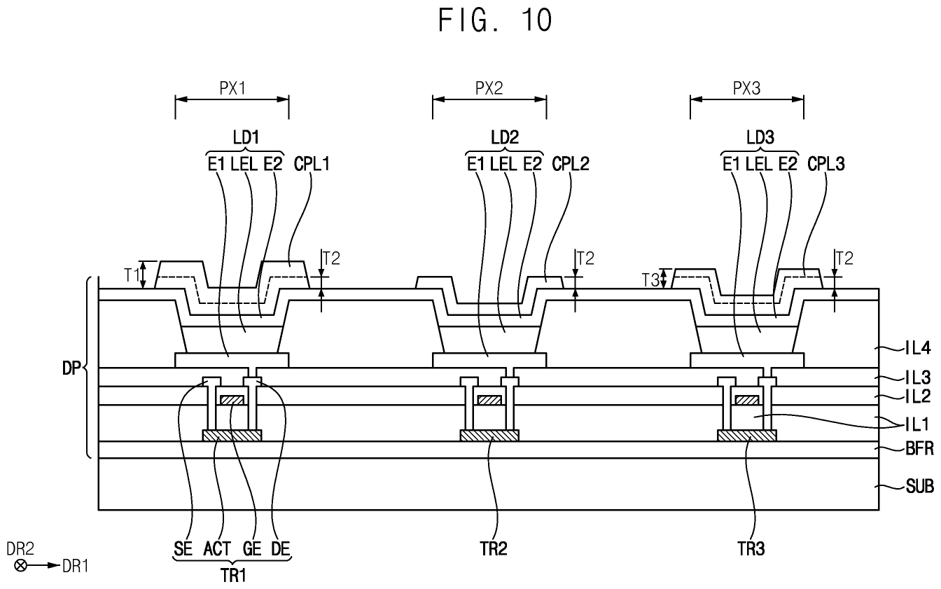

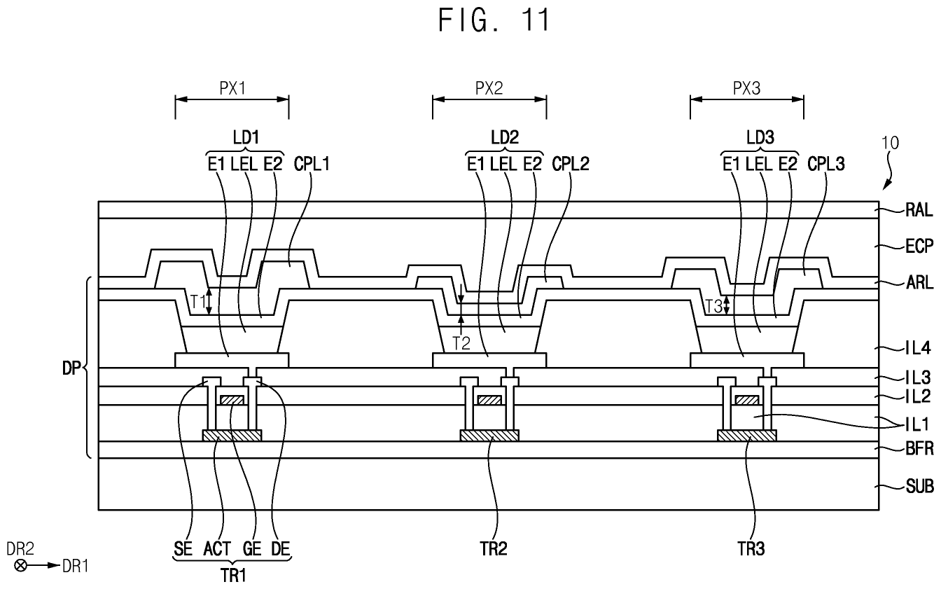

Referring to FIGS. 9 and 10, the plurality of capping layers may be formed on the first, second, and third light emitting diodes LD1, LD2, and LD3. The plurality of capping layers may include the first, second, and third capping layers CPL1, CPL2, and CPL3. The first, second, and third capping layers CPL1, CPL2, and CPL3 may overlap the first, second, and third light emitting diodes LD1, LD2, and LD3, respectively. The first, second, and third capping layers CPL1, CPL2, and CPL3 may be spaced apart from each other. In addition, the first, second, and third capping layers CPL1, CPL2, and CPL3 may have different optical thicknesses.

In an embodiment, the first, second, and third capping layers CPL1, CPL2, and CPL3 may have the same refractive index, be formed of the same material, and may have different thicknesses. However, the present disclosure is not limited thereto, and in another embodiment, the first, second, and third capping layers CPL1, CPL2, and CPL3 may have the same thickness, different refractive indices, and include different materials.

In an embodiment, the first, second, and third capping layers CPL1, CPL2, and CPL3 may be formed through a fine metal mask (FMM).

Referring to FIG. 9, when forming the first, second, and third capping layers CPL1, CPL2, and CPL3, first, the first, second, and third capping layers CPL1, CPL2, and CPL3 may have a common layer thickness T2 to each other and the common layer thickness T2 may be stacked on the first, second, and third light emitting diodes LD1, LD2, and LD3.

The common layer thickness T2 may be the smallest among the layer thicknesses of the first, second, and third capping layers CPL1, CPL2, and CPL3. For example, when the layer thickness T2 of the second capping layer CPL2 is the smallest, a first preliminary capping layer PCPL1, the second capping layer CPL2, and a third preliminary capping layer PCPL3 may be formed on the first, second, and third light emitting diodes LD1, LD2, and LD3, each having the layer thickness T2 of the second capping layer CPL2, respectively. An additional layer thickness other than the common layer thickness can be stacked on one or two of the first, second, and third capping layers, wherein the first, second, and third capping layers have different layer thicknesses.

Further referring to FIG. 10, an additional layer thickness other than the common layer thickness T2 among the first, second, and third capping layers CPL1, CPL2, and CPL3 may be stacked. That is, since the layer thickness T1 of the first capping layer CPL1 is greater than the layer thickness T2 of the second capping layer CPL2, the additional layer thickness excluding the layer thickness T2 of the second capping layer CPL2 among the layer thickness T1 of the first capping layer CPL1 may be stacked. Similarly, since the layer thickness T3 of the third capping layer CPL3 is greater than the layer thickness T2 of the second capping layer CPL2, the additional layer thickness excluding the layer thickness T2 of the second capping layer CPL2 among the layer thickness T3 of the third capping layer CPL3 may be stacked. In this case, the additional layer thickness of the first capping layer CPL1 and the additional layer thickness of the third capping layer CPL3 may be separately stacked with the layer thickness T2 of the second capping layer CPL2. However, the present disclosure is not limited thereto, and in another embodiment, the additional layer thickness of the first capping layer CPL1 and the additional layer thickness of the third capping layer CPL3 may be simultaneously stacked.

Accordingly, the first, second, and third capping layers CPL1, CPL2, and CPL3 having different layer thicknesses may be formed. For example, the layer thickness T1 of the first capping layer CPL1 may be between about 32 nanometers and about 40 nanometers. The layer thickness T2 of the second capping layer CPL2 may be between about 12 nanometers and about 20 nanometers. The layer thickness T3 of the third capping layer CPL3 may be between about 20 nanometers and about 30 nanometers.

Referring to FIG. 11, the anti-reflection layer ARL, the encapsulation layer ECP, and the reflection control layer RAL may be sequentially formed on the first, second, and third capping layers CPL1, CPL2, and CPL3. Thus, the display device 10 may be formed. However, the present disclosure is not limited thereto, and in another embodiment, the anti-reflection layer ARL, the filler FL, the encapsulation substrate ECP′, and the reflection control layer RAL may be sequentially formed on the first, second, and third capping layers CPL1, CPL2, and CPL3.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a base substrate;
first, second, and third light emitting diodes disposed on the base substrate, wherein the first, second, and third light emitting diodes each emit light of a different color; and
first, second, and third capping layers respectively disposed on the first, second, and third light emitting diodes, wherein the first, second, and third capping layers have different optical thicknesses.

2. The display device of claim 1, wherein the first, second, and third capping layers overlap the first, second, and third light emitting diodes, respectively.

3. The display device of claim 1, wherein the first light emitting diode emits red light, the second light emitting diode emits green light, and the third light emitting diode emits blue light.

4. The display device of claim 1, wherein an optical thickness of each of the first, second, and third capping layers is defined by multiplying a layer thickness of each of the first, second, and third capping layers by a refractive index of each of the first, second, and third capping layers.

5. The display device of claim 4, wherein an optical thickness of the first capping layer is between about 60 nanometers and about 90 nanometers, an optical thickness of the second capping layer is between about 20 nanometers and about 50 nanometers, and an optical thickness of the third capping layer is between about 35 nanometers and about 65 nanometers.

6. The display device of claim 1, wherein the first, second, and third capping layers have a same refractive index.

7. The display device of claim 6, wherein the first, second, and third capping layers include a same material as each other.

8. The display device of claim 6, wherein the first, second, and third capping layers have different layer thicknesses.

9. The display device of claim 8, wherein a layer thickness of the first capping layer is between about 32 nanometers and about 40 nanometers, a layer thickness of the second capping layer is between about 12 nanometers and about 20 nanometers, and a layer thickness of the third capping layer is between about 20 nanometers and about 30 nanometers.

10. The display device of claim 1, wherein the first, second, and third capping layers have a same layer thickness as each other.

11. The display device of claim 10, wherein the first, second, and third capping layers include different materials.

12. The display device of claim 10, wherein the first, second, and third capping layers have different refractive indices.

13. The display device of claim 12, wherein a refractive index of the first capping layer is greater than a refractive index of the second capping layer and a refractive index of the third capping layer, and
the refractive index of the third capping layer is greater than the refractive index of the second capping layer.

14. The display device of claim 1, wherein each of the first, second, and third capping layers includes an organic material.

15. The display device of claim 1, further comprising:
an encapsulation layer disposed on the first, second, and third capping layers and covering the first, second, and third capping layer.

16. The display device of claim 15, further comprising:
a reflection control layer disposed on the encapsulation layer.

17. A display device comprising:
a base substrate;
first, second, and third light emitting diodes disposed on the base substrate, wherein the first, second, and third light emitting diodes each emit light of a different color;
first, second, and third capping layers respectively disposed on the first, second, and third light emitting diodes, wherein the first, second, and third capping layers have different optical thicknesses;
an encapsulation substrate disposed on the first, second, and third capping layers; and
a filler filling between the first, second, and third capping layers and the encapsulation substrate.

18. A method of manufacturing a display device, the method comprising:
forming first, second, and third light emitting diodes that emits light of different colors on a base substrate; and
forming first, second, and third capping layers having different optical thicknesses on the first, second, and third light emitting diodes.

19. The method of claim 18, wherein the first, second, and third capping layers have different layer thicknesses.

20. The method of claim 19, wherein the forming the first, second, and third capping layers includes:
stacking the first, second, and third capping layers having a common layer thickness on the first, second, and third light emitting diodes; and
stacking an additional layer thickness other than the common thickness on one or two of the first, second, and third capping layers.
